(19) United States
(12) Patent Application Publication
(10) Pub. No.: US 2012/0234382 A1
(43) Pub. Date: Sep. 20, 2012

(54) SOLAR CELL AND METHOD OF MANUFACTURING THE SAME

(76) Inventors: Min PARK, Yongin-si (KR); Min-Seok Oh, Yongin-si (KR); Yun-Seok Lee, Yongin-si (KR); Nam-Kyu Song, Yongin-si (KR); Cho-Young Lee, Yongin-si (KR); Hoon-Ha Jeon, Yongin-si (KR); Yeon-Ik Jang, Yongin-si (KR)

(21) Appl. No.: 13/293,010

(22) Filed: Nov. 9, 2011

(30) Foreign Application Priority Data
Mar. 18, 2011 (KR) 10-2011-0024262

(51) Int. Cl. H01L 31/0232; H01L 31/18

(52) U.S. Cl. 136/256; 438/71; 257/E31.13

(57) ABSTRACT

A solar cell and a method of manufacturing the solar cell, the solar cell including a first surface configured to receive incident sunlight and having a concavo-convex pattern, a substantially flat second surface opposite to the first surface, a first doped layer formed as a crystalline silicon layer having a first dopant, and a second doped layer formed as an amorphous silicon layer having a second dopant. The processes for forming these layers, with the exception of forming the first doped layer, are performed at a low temperature. Accordingly, reflectivity of sunlight may be minimized, a high terminal voltage may be generated, and a wafer including the solar cell can be kept from being bent.

### PRIORITY STATEMENT

This application claims priority under 35 U.S.C. §119 to Korean Patent Application No. 2011-0024262, filed on Mar. 18, 2011, in the Korean Intellectual Property Office (KIPO), the contents of which are herein incorporated by reference in their entireties.

### BACKGROUND OF THE INVENTION

1. Field of the Invention

Embodiments of the present invention relate generally to a solar cell and a method of manufacturing the solar cell. More particularly, embodiments of the present invention relate to methods and apparatuses for making crystalline-type solar cells having higher efficiency.

2. Description of the Related Art

A solar cell is an energy conversion element converting light to electric energy using the photovoltaic effect. When sunlight is incident upon a substrate of the solar cell, electrons and holes are generated inside of the solar cell. The electrons and the holes respectively drift to positive and negative poles of the solar cell, so that a photo-electromotive force is generated. The photo-electromotive force is generated by a potential difference between the positive and negative poles. Thus, when the solar cell is loaded, an electric current flows.

Generally, crystalline-type solar cells can be made as hetero junction solar cells and screen-printing solar cells. Both surfaces of the hetero-junction solar cell have a pyramid shape, and thus reflectivity of incident light is high much incident light tends to be lost. The screen-printing solar cell is typically formed at high temperatures, which can bend or warp its wafer. Thus, screen-printing solar cells tend to be ill-suited to thin-film wafers, and their terminal voltage tends to be relatively low.

### SUMMARY OF THE INVENTION

Example embodiments of the present invention provide a solar cell capable of reducing or minimizing a reflectivity of incident light, having relatively high terminal voltage, and being well-suited for a thin-film wafer.

Example embodiments of the present invention also provide a method of manufacturing the solar cell.

According to an example embodiment of the present invention, the solar cell includes a base substrate, a first doped layer, a second doped layer, a first transparent conductive layer and a second electrode. The base substrate includes a first surface configured to receive incident sunlight, and a second surface opposite to the first surface. The first doped layer is formed on the second surface, and includes a first dopant. The second doped layer is formed on the first surface, and includes a second dopant. The first transparent conductive layer is formed on the second doped layer. The first electrode is formed on the first doped layer, and in particular can be formed on substantially an entire surface of the first doped layer. The second electrode is formed on the first transparent conductive layer, and in particular can be formed over a portion of a surface of the first transparent conductive layer.

In an example embodiment, the first surface may include a concavo-convex pattern, and the second surface may be substantially flat.

In an example embodiment, the base substrate may include crystalline silicon (c-Si), and the second doped layer may include at least one of amorphous silicon (a-Si), amorphous silicon carbide (a-SiC) and amorphous silicon germanium (a-SiGe).

In an example embodiment, the first doped layer is formed via a diffusion method.

In an example embodiment, the solar cell may further include a passivation layer positioned between the second surface of the base substrate and the second doped later. The passivation layer may include an intrinsic semiconductor.

In an example embodiment, a thickness of the second doped layer may be between about 50 Å and about 200 Å, and a thickness of the first transparent conductive layer may be between about 700 Å and about 1200 Å.

In an example embodiment, each of the first and second electrode may comprise a single-layer structure including at least one of aluminum (Al), silver (Ag), and copper (Cu), or may comprise a multi-layer structure including at least one of an alloy of titanium and tungsten (TiW), tin (Sn), nickel (Ni) in addition to at least one of aluminum (Al), silver (Ag), and copper (Cu).

In an example embodiment, the solar cell may further include a second transparent conductive layer positioned between the first doped layer and the first electrode.

In an example embodiment, the solar cell may further include an anti-reflection layer positioned between the first doped layer and the first electrode. The anti-reflection layer may include a plurality of contact holes through which the first doped layer and the first electrode are connected to each other. The first doped layer may include a doped patterns overlapping the contact holes.

According to another example embodiment of the present invention, a method of manufacturing a solar cell is provided. In the method, a base substrate including a first surface for receiving sunlight and a second surface opposite to the first surface is formed. A protection layer is formed on the first surface. A first doped layer having a first dopant is formed on the second surface of the base substrate. The protection layer is removed from the first surface of the base substrate. A second doped layer having a second dopant is formed on the first surface of the base substrate. A first transparent conductive layer is formed on the second doped layer. A first electrode is formed over substantially an entire surface of the first doped layer. A second electrode is formed on a portion of the first transparent conductive layer.

In an example embodiment, the forming a base substrate may further include forming a concavo-convex pattern on the first and second surfaces of the base substrate, forming the protection layer on the first surface of the base substrate, and removing the concavo-convex pattern from the second surface of the base substrate.

In an example embodiment, the first doped layer is formed via a diffusion method using phosphorus oxychloride (POCl₃) or boron three bromides (BBr₃).

In an example embodiment, the removing the protection layer may include removing a phosphor-silicate glass (PSG) layer or a boron-silicate glass (BSG) layer formed via the diffusion method, and cleaning the base substrate. Removing the protection layer and the PSG layer or the BSG layer may be performed via a wet etching process using a solution, and may be performed successively or at the same time.

In an example embodiment, the protection layer may be removed at a temperature not more than about 200° C., and the second doped layer, the first transparent conductive layer, the first electrode and the second conductive layer may be formed at a temperature not more than about 200° C.

According to the present invention, reflectivity of incident light may be reduced or minimized and a wafer including the solar cell may be kept from being bent.

In addition, a manufacturing process may be simplified, and most of the manufacturing processes may be performed at a low temperature, preventing warping of the wafer.

### BRIEF DESCRIPTION OF THE DRAWINGS

The above and other features and advantages of the present invention will become more apparent by describing in detail the preferred embodiments thereof with reference to the accompanying drawings, in which:

FIG. 1 is a perspective view illustrating a solar cell according to an example embodiment of the present invention;

FIG. 2 is a cross-sectional view taken along a line I-I′ in FIG. 1;

FIG. 3A is a cross-sectional view for explaining a light advancing pathway in a substrate having pyramid shapes on both sides of the substrate;

FIG. 3B is a cross-sectional view for explaining a light advancing pathway in a substrate having the pyramid shape on a side of the substrate;

FIGS. 4A, 4B, 4C, 4D, 4E, 4F, 4G and 4H are cross-sectional views for explaining a manufacturing process of the solar cell in FIG. 2;

FIG. 5 is a perspective view illustrating a solar cell according to another example embodiment of the present invention;

FIG. 6 is a cross-sectional view taken along a line II-II′ in FIG. 5;

FIG. 7 is a perspective view illustrating a solar cell according to still another example embodiment of the present invention;

FIG. 8 is a cross-sectional view taken along a line III-III′ in FIG. 7;

FIG. 9 is a perspective view illustrating a solar cell according to still another example embodiment of the present invention;

FIG. 10 is a cross-sectional view taken along a line IV-IV′ in FIG. 9; and

FIGS. 11A, 11B, 11C and 11D are cross-sectional views for explaining a manufacturing process of the solar cell in FIG. 9.

### DETAILED DESCRIPTION OF THE INVENTION

Hereinafter, embodiments of the present invention will be explained in detail with reference to the accompanying drawings.

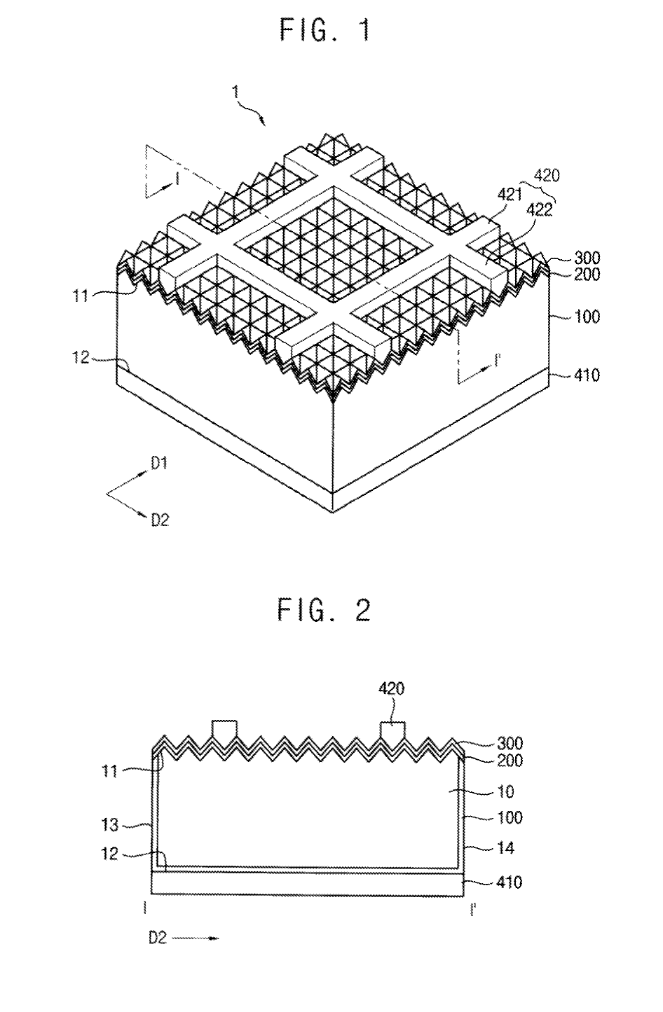

FIG. 1 is a perspective view illustrating a solar cell according to an example embodiment of the present invention. FIG. 2 is a cross-sectional view taken along a line I-I′ in FIG. 1.

Referring to FIGS. 1 and 2, the solar cell 1 according to the present example embodiment includes a base substrate 10, a first doped layer 100, a second doped layer 200, a transparent conductive layer 300, a first electrode 410 and a second electrode 420.

The base substrate 10 includes a first surface 11 into which sunlight is incident, a second surface 12 opposite to the first surface 11, a third surface 13 connecting the first surface 11 with the second surface 12, and a fourth surface 14 opposite to the third surface 13. The base substrate 10 may be an n-type crystalline silicon substrate. For example, the base substrate 10 includes an element in Group V, such as Phosphorus (P), Arsenic (As), Antimony (Sb), Bismuth (Bi), etc. The base substrate 10 may be a crystalline silicon substrate, and may be a single-crystalline substrate or a poly-crystalline substrate.

The first surface 11 of the base substrate 10 includes a concavo-convex pattern. The concavo-convex pattern increases the light absorbing area of surface 11 and diversifies light advancing pathways, making it more likely that any given light pathway will eventually intersect surface 11. Thus, light absorption is increased, and corresponding amount of electron hole pairs (EHPs) is increased. The number of EHPs formed increases with increasing area of surface 11. Uneven or concavo-convex patterns having shapes that increase total surface area are thus beneficial. For example, the concavo-convex pattern may have a pyramid shape. Also, the pyramid shape is not limited to that of a quadrangular pyramid, and may include all kinds of shapes having an apex and a slope, such as a hemisphere shape. Indeed, the pattern may be any uneven or non-planar pattern that acts to increase the available surface area over that of a planar surface. The concavo-convex pattern may be formed on the first and second surfaces 11 and 12 via a dipping texturing method or via an in-line texturing method in which the base substrate is dipped in solution.

The second surface 12 is formed via a wet etching process in which the concavo-convex pattern formed on the second surface 12 is removed. In the wet etching process, the base substrate 10, which is a crystal silicon substrate, is exposed to an alkaline solution which removes the concavo-convex pattern from the second surface 12. In this case, a protection layer is formed on the first surface 11 to protect the concavo-convex pattern of the first surface 11 from being exposed to the alkaline solution. The alkaline solution may include potassium chloride (KOH), sodium chloride (NAOH) and tetra methyl ammonium hydroxide (TMAH), etc. The light incident to the first surface 11 is reflected onto the second surface 12. The second surface 12 is substantially flat, thus presenting a simpler light advancing pathway. This simpler pathway means less chance of light interference, which increases the amount of light absorbed by the solar cell 1.

Advantages and disadvantages of the concavo-convex patterns of the first and second surfaces 11 and 12 are explained later.

In the present example embodiment, the base substrate 10 includes an n-type silicon substrate. Alternatively, the base substrate 10 may include a p-type silicon substrate.

The first doped layer 100 is formed on the second, third and fourth surfaces 12, 13 and 14 of the base substrate 10. The first doped layer 100 may be an (n+)-type semiconductor layer doped with a first dopant at a high concentration. The first dopant may include an element in Group V such as phosphorus (P). The first doped layer 100 can be formed via a diffusion process in which the first dopant is diffused into the base substrate 10 to form the first doped layer 100. For example, phosphorus oxychloride (POCl₃) can be provided to the base substrate 10, and the base substrate 10 can be heated, so that phosphorus (P) from the phosphorus oxychloride (POCl₃) is diffused into the surfaces of the base substrate 10 as the first dopant. The portion of base substrate 10 in which the first dopant is diffused then becomes the first doped layer 100. Liquid or gaseous phosphorus oxychloride (POCl₃) may be provided. In this case, the protection layer is formed on the first surface 11, and then the diffusion process is performed, so that the first doped layer 100 (which is an (n+)-type doped layer) is formed on the second, third and fourth surfaces 12, 13 and 14, but not on the first surface 11. The first doped layer is formed at high temperature, typically between about 700° C. and about 1000° C.

Alternatively, when the base substrate 10 is a p-type silicon substrate, boron tree bromides (BBr₃) are provided to the base substrate 10 to form the first doped layer 100 via a diffusion process. The protection layer is formed on the first surface 11 of the base substrate 10, liquid or gaseous boron tree bromides (BBr₃) are provided to the base substrate 10, and the base substrate 10 is heated, so that boron (B) is diffused into the base substrate 10 as the first dopant. This forms the first doped layer 100 as a p-type semiconductor doped layer on the second, third and fourth surfaces 12, 13 and 14.

An amorphous second doped layer 200 is formed on the first surface 11 of the base substrate 10 (after removal of the protection layer from first surface 11). The second doped layer 200 may include at least one of amorphous silicon (a-Si), amorphous silicon carbide (a-SiC) and amorphous silicon germanium (a-SiGe). In addition, the second doped layer 200 includes a second dopant, which may include an element in Group III such as boron (B), aluminum (Al), gallium (Ga), indium (In), etc. The second doped layer 200 may include a p-type semiconductor. A thickness of the second doped layer 200 may be between about 50 Å and about 200 Å. The second doped layer 200 may be formed via a deposition method such as plasma chemical vapor deposition (PECVD).

A passivation layer (not shown) may be formed between the first surface 11 of the base substrate 10 and the second doped layer 200. The passivation layer may include one of amorphous silicon (a-Si) and the amorphous silicon carbide (a-SiC), and may include an intrinsic semiconductor. The passivation layer may be formed via PECVD. The passivation layer may prevent holes and electrons from drifting between the base substrate 10 and the second doped layer 200, and between the base substrate 10 and the first doped layer 100, and thus the holes and the electrons may be prevented from being recombined.

When the base substrate 10 is a p-type crystalline semiconductor substrate, the second doped layer 200 may include an n-type amorphous semiconductor.

The transparent conductive layer 300 is formed on the second doped layer 200. The transparent conductive layer 300 electrically connects the second doped layer 200 to the second electrode 420, and the sunlight incident into the first surface 11 passes through the transparent conductive layer 300. The transparent conductive layer 300 may include one of an indium-based oxide such as indium-tin oxide (ITO), indium-tungsten oxide (IWO), indium-tantalum oxide (ITaO), indium-gallium oxide (IGO) or the like, a zinc-based oxide such as ZnO:B, ZnO:Al or the like, and a combination of indium-based oxide and zinc-based oxide. The transparent conductive layer 300 may be a metal layer doped with the above-mentioned material. A thickness of the transparent conductive layer 300 may be between about 700 Å and about 1200 Å. The transparent conductive layer 300 may be formed via chemical vapor deposition (CVD), an evaporation method, a sputtering method, or the like.

The first electrode 410 is entirely formed on the first doped layer 100, and the second electrode 420 is partially formed on the transparent conductive layer 300. For example, the first electrode 410 is electrically connected to the first doped layer 100, and the second electrode 420 is electrically connected to the second doped layer 200 via the transparent conductive layer 300. The second electrode 420 may include a plurality of bus lines 421 extending along a first direction D1, and a plurality of finger lines 422 extending along the second direction D2. Here, the lines 421 are substantially perpendicular to lines 422, so that the lines cross each other.

The first and second electrodes 410 and 420 may each include at least one of aluminum (Al), silver (Ag), copper (Cu), or an alloy thereof. Each of the first and second electrodes 410 and 420 may have a single-layer structure including an element, or may have a multi-layer structure including Cu/TiW, Sn/Cu/TiW, Sn/Cu/Ni/Ag, Sn/Cu/Ni, Sn/Cu, etc. For example, when each of the first and second electrodes 410 and 420 has a multi-layer structure, one layer may be a capping layer preventing the electrodes from being oxidized, and another layer may be a seed layer helping plating of the electrodes. Both the capping layer and the seed layer may include at least one of an alloy of titanium and tungsten, tin (Sn) and nickel (Ni). The first and second electrodes 410 and 420 are formed via a screen printing method, an ink jetprinting method, or the like, as well as a subsequent deforming process at a low temperature not higher than about 200° C. The first doped layer 100 is formed by diffusing the above-described first dopant into the crystalline substrate, and the second doped layer 200 is formed as an amorphous semiconductor layer including the second dopant. This forms a hetero junction of crystalline silicon and amorphous silicon. The energy band gap of crystalline semiconductor is about 1.1 eV, and the energy band gap of amorphous semiconductor is between about 1.7 eV and about 1.8 eV. Since, the solar cell 1 according to the present example embodiment includes a hetero-junction of crystalline semiconductor and amorphous semiconductor, the solar cell 1 absorbs light having a broad range of wavelengths (due to the difference in energy band gaps), and thus the solar cell 1 has a high terminal voltage (Voc). The terminal voltage is an operating voltage when an output current is 0, and is generally the highest voltage that the solar cell 1 generates. As the terminal voltage is increased, so is the maximum electric energy that can be produced. Thus, the efficiency of the solar cell may be increased.

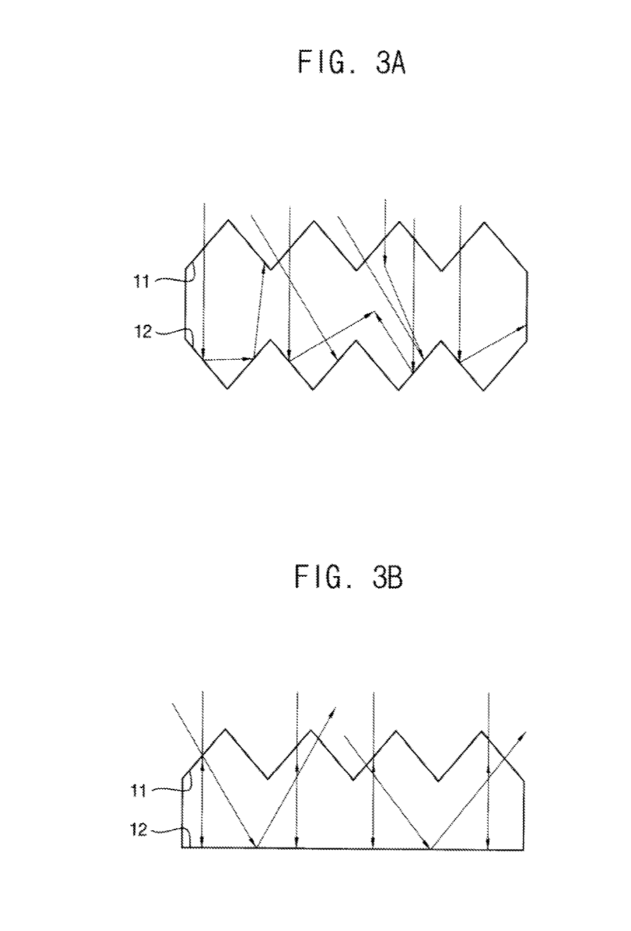

FIG. 3A is a cross-sectional view for explaining light advancing pathways in a substrate having pyramid shapes on both sides of the substrate. FIG. 3B is a cross-sectional view for explaining light advancing pathways in a substrate having pyramid shapes on one side of the substrate.

Referring to FIG. 3A, the substrate includes a concavo-convex pattern with pyramid shapes. The concavo-convex pattern is formed on the first surface 11 onto which sunlight falls incident, as well as the second surface 12 opposite to the first surface 11. Referring to FIG. 3B, the substrate includes a concavo-convex pattern formed on the first surface 11, but the second surface 12 of the substrate is flat. Incident light passes through the concavo-convex pattern formed on the first surface 11, and is reflected from the second surface 12. When a concavo-convex pattern is formed on the second surface 12, light is reflected by two reflective surfaces that are inclined with angles different from each other. Accordingly, reflected light may take various different paths, so that light is reflected in an irregular manner. Increasing the number of light paths increases the chance that some paths may cross, which in turn increases the chance that some light rays will interfere with each other. This reduces the number of photons of sunlight incident into the solar cell. Alternatively, when the second surface 12 is flat, an angle of the reflective surface is constant at any position. The number of light advancing pathways is thus decreased, thus reducing the chance of interference. Accordingly, this configuration increases the number of photons of sunlight incident into the solar cell, so that absorbed sunlight may be more effectively converted into energy. In addition, the first electrode 410 may be more easily formed.

In the solar cell 1 of the present example embodiment, when a photon of sunlight is incident into the first surface 11, a hole and electron are generated in the base substrate 10. In this case, since the second surface 12 of the solar cell 1 is flat, light travels a relatively short path before being absorbed by the solar cell 1, perhaps only reflecting once off of surface 12, so that light is relatively less likely to be extinguished by interference. Thus, the number of photons absorbed into the inside of the solar cell 1 may be increased.

The resulting hole drifts to the first doped layer 100 by an electric field generated at a PN-junction between the base substrate 10 and the second doped layer 200. The electron drifts to the second doped layer 200. The second doped layer 200 includes amorphous silicon and the first doped layer 100 includes the crystalline silicon, so that when the first doped layer 100 is combined with the second doped layer 200, an energy band gap generated between the first and second doped layers 100 and 200 is relatively high. The electrons drifting to the second doped layer 200 pass through the transparent conductive layer 300 and are accumulated at the second electrode 420. Meanwhile, the holes drifting to the first doped layer 100 are accumulated at the first electrode 410.

Accordingly, a potential difference is generated by the holes and the electrons respectively accumulated at the first and second electrodes 410 and 420, and thus the solar cell 1 produces electrical energy from the incident sunlight.

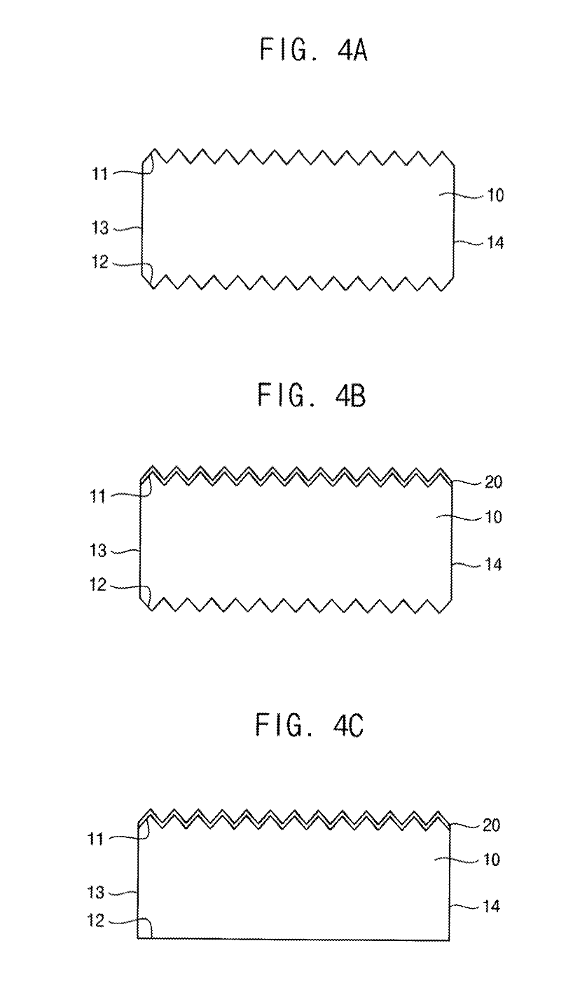

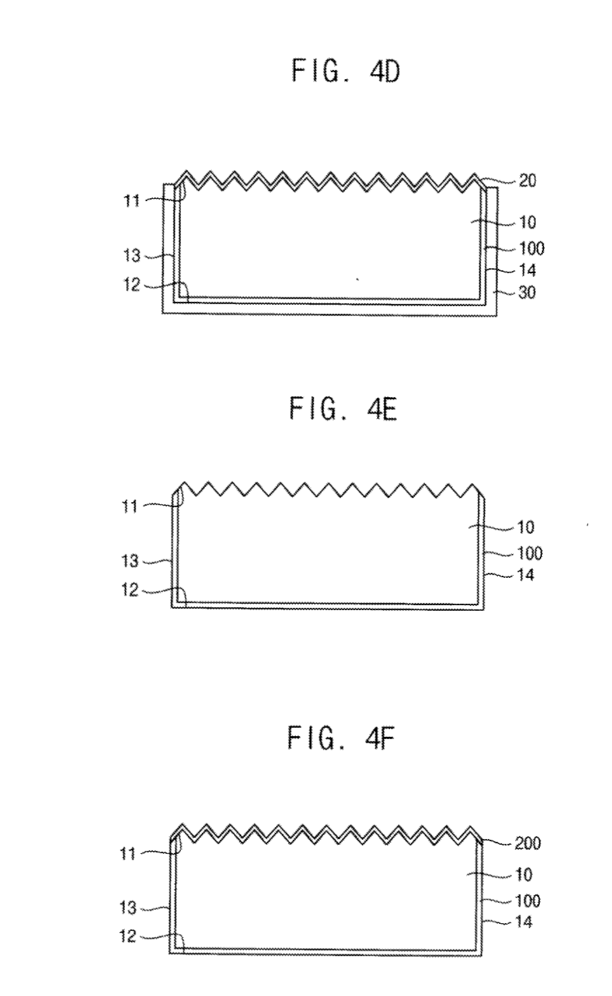

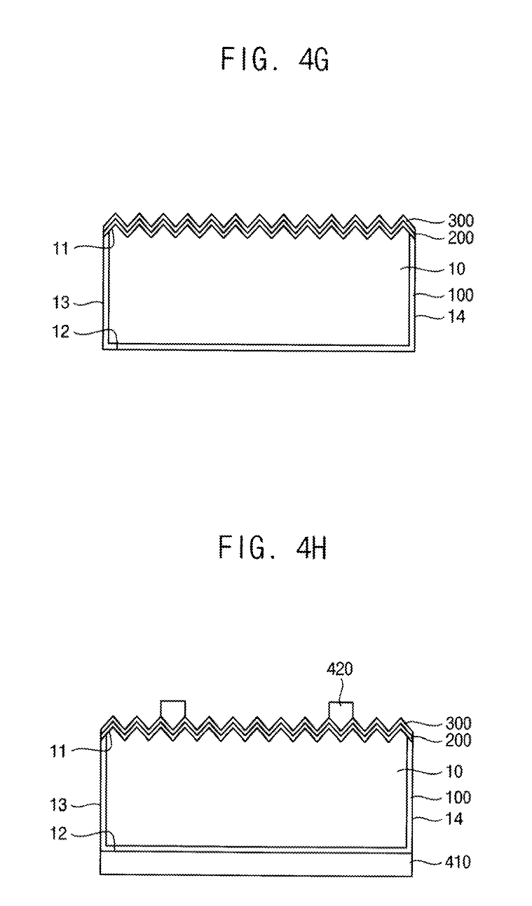

FIGS. 4A, 4B, 4C, 4D, 4E, 4F, 4G and 4H are cross-sectional views for explaining a manufacturing process of the solar cell in FIG. 2.

Referring to FIGS. 2 and 4A, the n-type silicon substrate is cut to a predetermined size. A cutting surface of the base substrate 10 is partially etched to form the base substrate 10. Defects generated during a cutting process of the base substrate 10 may be removed via a wet etching process using an acid solution. The base substrate 10 includes first surface 11 onto which light is incident, second surface 12 opposite to the first surface 11, third surface 13 connecting the first surface 11 with the second surface 12, and fourth surface 14 opposite to the third surface 13. The concavo-convex pattern is formed on the first and second surfaces 11 and 12 via a dipping texturing method or in-line texturing method in which the base substrate 10 is dipped in solution. As above, this concavo-convex pattern increases the light absorbing area and diversifies the light advancing pathway. Accordingly, the area which incident light reaches is increased, increasing the number of electrode-hole pairs generated. The concavo-convex pattern may have pyramid shapes, but the shape of the concavo-convex pattern is not limited thereto.

In the present example embodiment, the solar cell 1 is manufactured using a base substrate 10 that is an n-type silicon substrate, but alternatively, a p-type silicon substrate may be used.

Referring to FIGS. 2 and 4B, a protection layer 20 is formed on the first surface 11 of the base substrate 10. The protection layer 20 prevents the concavo-convex pattern formed on the first surface 11 from being removed during the process in which the concavo-convex pattern formed on the second surface 12 is removed, and the doped layer is prevented from being formed on the first surface 11 during the process in which the first doped layer 100 is formed on the second surface 12. The protection layer 20 may formed via a CVD method, a spin coating method, a screen printing method, or the like. The protection layer 20 may include an oxide, a nitride such as silicon oxide (SiOx), aluminum oxide (AlxOy), zinc oxide (ZnO), silicon nitride (SiNx), silicon carbide (SixCy), silicon oxy nitride (SiOxNy), carbide and a photoresistor.

Referring to FIGS. 2 and 4C, the concavo-convex pattern formed on the second surface 12 of the base substrate 10 is removed, so that the second surface 12 is flat. The concavo-convex pattern formed on the second surface 12 is removed via a wet etching process using an alkaline solution such as potassium chloride (KOH), sodium chloride (NAOH), tetra methyl ammonium hydroxide (TMAH), etc. The concavo-convex pattern formed on the first surface 11 is not removed by the wet etching process, due to the presence of the protection layer 20.

Referring to FIGS. 2 and 4D, the first doped layer 100 is formed in the base substrate 10 via the above-described diffusion process. Phosphorus oxychloride (POCl₃) is provided to the base substrate 10 and the base substrate 10 is heated, so that phosphorus (P) from the phosphorus oxychloride (POCl₃) is diffused into surfaces of the base substrate 10 as the first dopant. This forms the first doped layer 100. The phosphorus oxychloride (POCl₃) may be provided in liquid or gaseous form. The protection layer 20 is formed on the first surface 11 during the diffusion process, so that the first dopant is not diffused into the first surface 11 and the first doped layer 100 (which is an (n+)-type doped layer) is formed on the second, third and fourth surfaces 12, 13 and 14. The first doped layer is formed at high temperature, between about 700° C. and about 1000° C. After the diffusion process, a phosphorus silicate glass (PSG) layer is formed on the second, third and fourth surfaces 12, 13 and 14 of the base substrate 10 due to a reaction between the silicon (Si) of the base substrate 10 and the phosphorus oxychloride (POCl₃). The PSG layer blocks a current from flowing in the solar cell 1.

In the present example embodiment, the protection layer 20 is formed on the first surface 11, and the first doped layer 100 is formed on the second, third and fourth surfaces 12, 13 and 14. Alternatively, the protection layer 20 may be formed on the first, third and fourth surfaces 11, 13 and 14, and the first doped layer 100 can be formed on the second surface 12. In addition, the first doped layer 100 formed on the third and fourth surfaces 13 and 14 may be removed by a laser. The first doped layer is formed at high temperature, between about 700° C. and about 1000° C. Alternatively, when the base substrate 10 is a p-type silicon substrate, boron three bromides (BBr₃) are provided to the base substrate 10 and the first doped layer 100 is formed as a (p+)-type semiconductor. In this case, a boron-silicate glass (BSG) layer is formed on the second, third and fourth surfaces 12, 13 and 14, and the BSG layer also blocks current from flowing in the solar cell 1.

Referring to FIGS. 2 and 4E, the PSG layer 30 or the BSG layer 30 and the protection layer 20 are removed. The PSG layer 30 or the BSG layer 30 and the protection layer 20 may be removed at the same time via a wet etching process using hafnium (HF) solution, RCA SC-1 solution, RCA SC-2 solution, etc. In addition, a natural oxide layer that may be formed on the base substrate 10 is removed, and the base substrate 10 is cleaned. Removal of the PSG layer 30, the protection layer 20 and the natural oxide layer, and cleaning of the base substrate 10 may be performed sequentially or at the same time.

The protection layer 20 is used as a protecting layer preventing the concavo-convex pattern formed on the first surface 11 from being removed during removal of the concavo-convex pattern formed on the second surface 12, and is also used to prevent formation of the first doped layer 100 on the first surface 11. Accordingly, forming and removing additional protecting layers in each process is integrated into one step, and thus the overall manufacturing process may be simplified.

Referring to FIGS. 2 and 4F, the second doped layer 200 having the second dopant is formed on the first surface 11 of the base substrate 10. The second doped layer 200 may include a p-type amorphous semiconductor. For example, the second doped layer 200 may include at least one of amorphous silicon (a-Si), amorphous silicon carbide (a-SiC) and amorphous silicon germanium (a-SiGe). The thickness of the second doped layer 200 may be between about 50 Å and about 200 Å. The second doped layer 200 may be formed via a process such as PECVD, etc. When using PECVD, the second doped layer 200 is formed at a temperature not higher than about 200° C.

Although not shown in figures, a passivation layer may be formed between the first surface 11 of the base substrate 10 and the second doped layer 200. The passivation layer may include at least one of amorphous silicon (a-Si) and amorphous silicon carbide (a-SiC), and may include an intrinsic semiconductor. Accordingly, the passivation layer may prevent holes and electrons from moving between the base substrate 10 (which includes an n-type semiconductor) and the second doped layer 200 (which includes an p-type semiconductor layer), and between the first doped layer 200 (including an (n+)-type semiconductor layer formed on the third and fourth surfaces 13 and 14) and the second doped layer 200 (including a p-type semiconductor), and thus the holes and the electrons may be prevented from being recombined with each other. The passivation layer may be formed via plasma chemical vapor deposition (PECVD), or any other suitable process.

When the base substrate 10 is formed as a p-type crystalline semiconductor substrate, the second doped layer 200 may be formed as an n-type amorphous semiconductor substrate.

Referring to FIGS. 2 and 4G, the transparent conductive layer 300 is formed on the second doped layer 200. The transparent conductive layer 300 includes one of an indium-based oxide such as indium-tin oxide (ITO), indium-tungsten oxide (IWO), indium-tantalum oxide (ITaO), indium-gallium oxide (IGO) or the like, a zinc-based oxide such as ZnO:B, ZnO:Al or the like, and a combination of indium-based oxide and zinc-based oxide. The transparent conductive layer 300 may be a metal layer doped with the above-mentioned material. The thickness of the transparent conductive layer 300 may be between about 700 Å and about 1200 Å. The transparent conductive layer 300 may be formed via a CVD method, an evaporation method, a sputtering method or a reactive plasma deposition (RPD) method, etc.

Referring to FIGS. 1, 2 and 4H, the first electrode 410 is formed on substantially the entirety of the first doped layer 100, and the second electrode 420 is formed to cover part of the transparent conductive layer 300. The first electrode 410 is electrically connected to the first doped layer 100, and the second electrode 420 is electrically connected to the second doped layer 200 through the transparent conductive layer 300. The second electrode 420 may include the bus lines 421 extending along the first direction D1, and the finger lines 422 extending along the second direction D2 substantially perpendicular to the first direction D1 so as to cross the lines 421. Generally, when an anti-reflection layer 500 is formed on a doped layer, an electrode is also formed. This electrode typically passes through the anti-reflection layer to be electrically connected to the doped layer, and is formed via the above-described deforming process. The deforming process is performed at relatively high temperature, not lower than about 700° C. In the present example embodiment, the second electrode 420 is electrically connected to the second doped layer 200 by the transparent conductive layer 300, and thus the deforming process is unnecessary. Instead, the first and second electrodes 410 and 420 are formed via a screen printing method, an ink-jet printing method, etc., and the subsequent deforming process is performed at relatively low temperatures, typically not more than 200° C.

The first and second electrodes 410 and 420 may include at least one of aluminum (Al), silver (Ag), copper (Cu), or alloys thereof. Each of the first and second electrodes 410 and 420 may have a single-layer structure including the above element, or may have a multi-layer structure including Cu/TiW, Sn/Cu/TiW, Sn/Cu/Ni/Ag, Sn/Cu/Ni, Sn/Cu, etc. For example, when each of the first and second electrodes 410 and 420 has a multi-layer structure, one layer may be a capping layer preventing the electrodes from being oxidized, and another may be a seed layer helping plating of the electrodes. Each of these layers may include at least one of an alloy of titanium and tungsten (TiW), tin (Sn) and nickel (Ni).

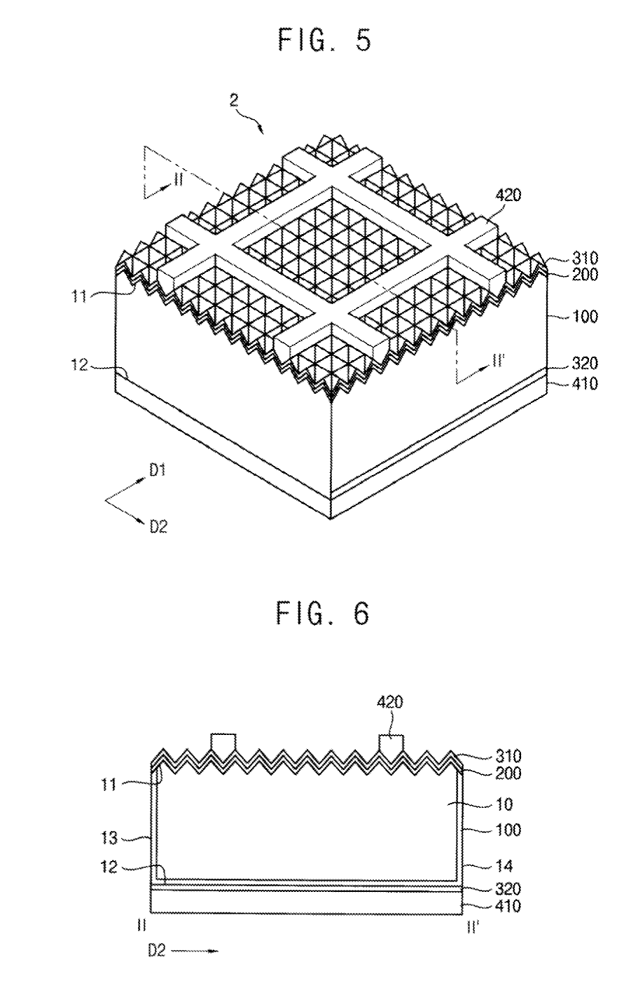

FIG. 5 is a perspective view illustrating a solar cell according to another example embodiment of the present invention. FIG. 6 is a cross-sectional view taken along a line II-II′ in FIG. 5

Referring to FIGS. 5 and 6, the solar cell 2 according to the present example embodiment is substantially the same as the solar cell 1 of the previous example embodiment of FIGS. 1 and 2, and any further explanation is omitted. However, the transparent conductive layer 300 of solar cell 1 of previous example embodiments is termed a first transparent conductive layer 310 in the present example embodiment to distinguish the first transparent conductive layer 310 from a second transparent conductive layer 320.

The solar cell 2 of the present example embodiment includes the base substrate 10, the first doped layer 100, the second layer 200, the first transparent conductive layer 310, the second transparent conductive layer 320, the first electrode 410 and the second electrode 420.

The first transparent conductive layer 310 is formed on the second doped layer 200, and the second transparent conductive layer 320 is formed between the first doped layer 100 and the first electrode 410. The first and second conductive layers 310 and 320 include an indium-based oxide such as indium-tin oxide (ITO), indium-tungsten oxide (IWO), indium-tantalum oxide (ITaO), indium-gallium oxide (IGO) or the like, a zinc-based oxide such as ZnO:B, ZnO:Al or the like, or a combination of indium-based oxide and zinc-based oxide. The first transparent conductive layer 310 may be a metal layer doped with the above-mentioned material. The thicknesses of the first and second conductive layers 310 and 320 may be between about 700 Å and about to 1200 Å. The second conductive layer 320 prevents the first electrode 410 from making contact with the first doped layer 100, and thus an element of the first electrode 410 is kept from being melted and permeating into the first doped layer 100. In addition, the second conductive layer 320 allows long-wavelength light reflected from the first electrode 410 to be more readily absorbed by the solar cell 2.

The method of manufacturing the solar cell 2 according to the present example embodiments is substantially the same as the method of manufacturing of the solar cell 1 of the previous example embodiment of FIG. 2. However, in the present example embodiment, the second conductive layer 320 is formed on the first doped layer 100. The second conductive layer 320 is formed via a CVD method, a evaporation method, a sputtering method or RPD method, etc.

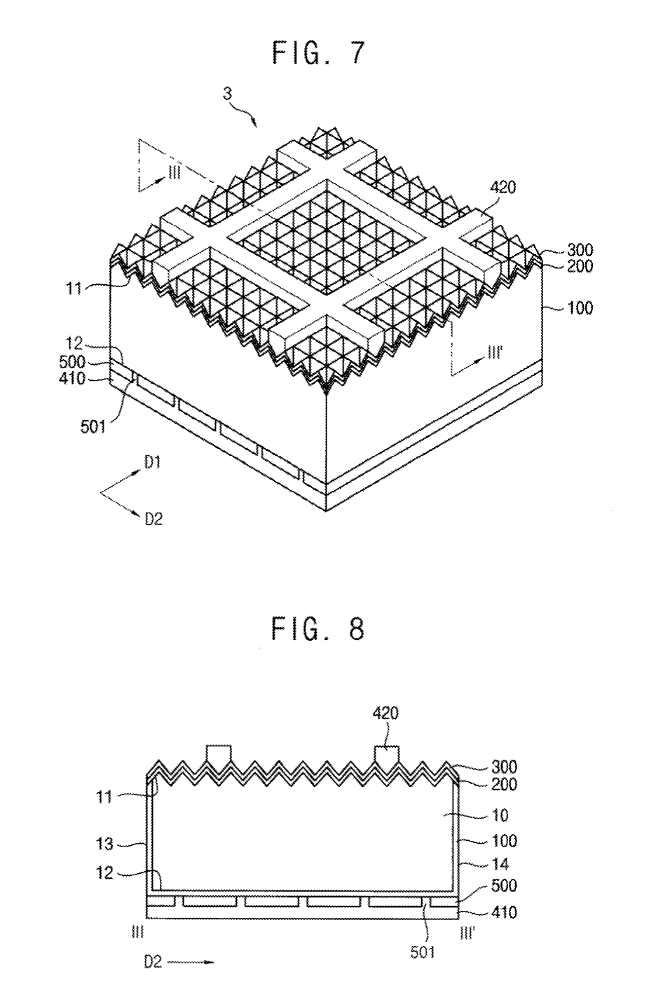

FIG. 7 is a perspective view illustrating a solar cell according to still another example embodiment of the present invention. FIG. 8 is a cross-sectional view taken along a line III-III′ in FIG. 7.

Referring to FIGS. 7 and 8, a solar cell 3 according to the present example embodiments is substantially the same as the solar cell 1 of the previous example embodiment of FIGS. 1 and 2, except for an anti-reflection layer 500 and contact holes 501 formed through the anti-reflection layer 500. Thus, any further explanation of common structures between this embodiment and that of FIGS. 1 and 2 will be omitted.

The solar cell 3 according to the present example embodiments includes the base substrate 10, the first doped layer 100, the second layer 200, the transparent conductive layer 300, the first electrode 410, the second electrode 420, the anti-reflection layer 500 and the contact holes 501.

The anti-reflection layer 500 is formed between the first doped layer 100 and the first electrode 410, and has the contact holes 501 formed therein. The anti-reflection layer 500 prevents the long-wavelength light from being reflected again, so that more of this light is absorbed into the solar cell 3. The contact holes 501 are formed through the anti-reflection layer 500 so that the first electrode 410 is electrically connected to the first doped layer 100. That is, the first electrode 410 is formed in the contact holes 501, so as to be electrically connected to the first doped layer 100.

The method of manufacturing the solar cell 2 of the present example embodiments is substantially the same as the method of manufacturing of the solar cell 1 of the previous example embodiment of FIG. 2. However, in the present example embodiment, the anti-reflection layer 500 is formed on the first doped layer 100. The anti-reflection layer 500 may be formed via a CVD method, an evaporation method, a sputtering method, etc. The contact holes 501 may be formed by a laser, via an edge paste method, a photolithography method, or the like.

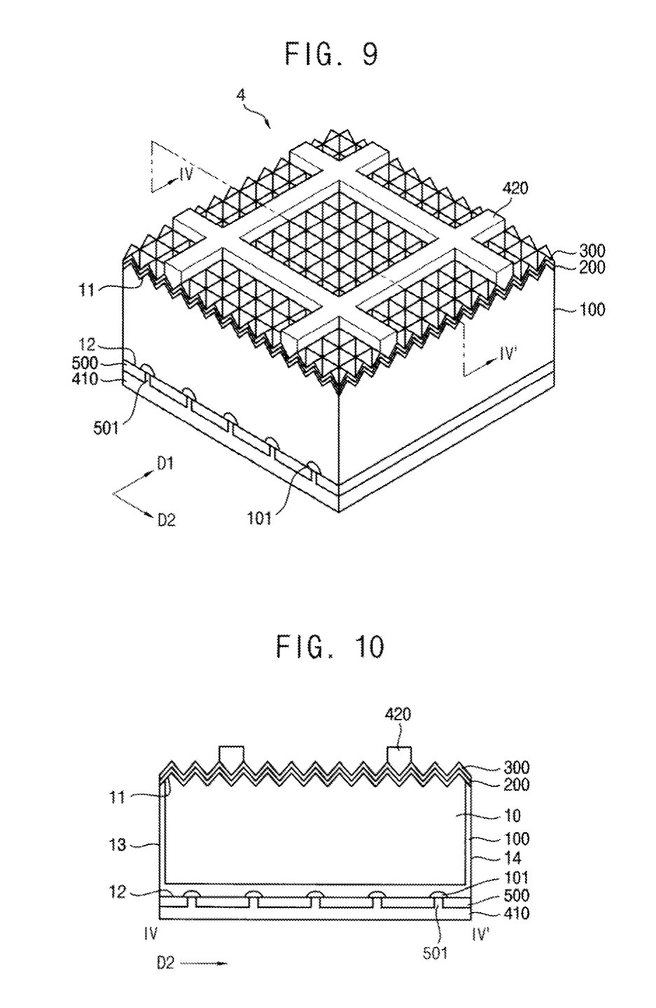

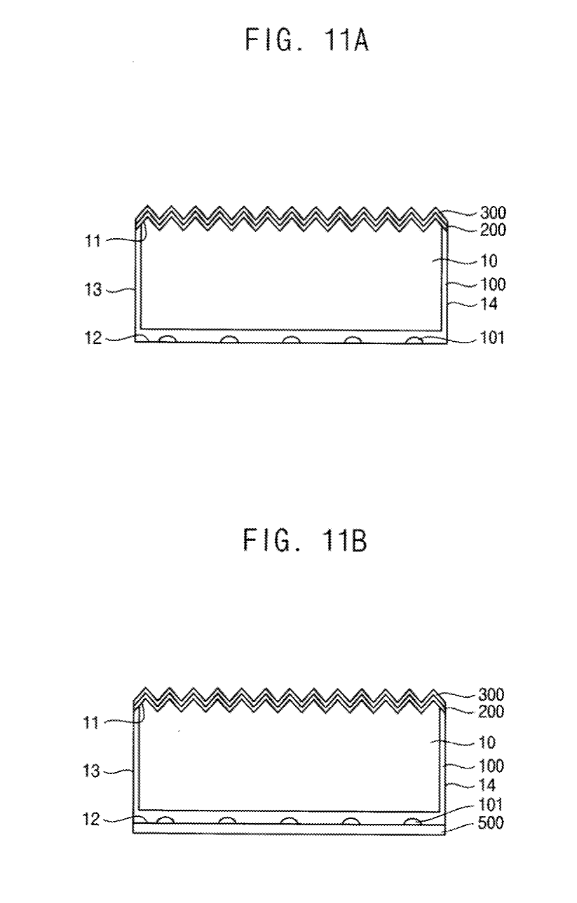

FIG. 9 is a perspective view illustrating a solar cell according to still another example embodiment of the present invention. FIG. 10 is a cross-sectional view taken along a line IV-IV′ in FIG. 9.

Referring to FIGS. 9 and 10, a solar cell 4 of the present example embodiments is substantially the same as the solar cell 3 of the previous example embodiment of FIGS. 7 and 8, except for doping patterns 101 formed in the first doped layer 100. Thus, any further explanation of common structures between this embodiment and that of FIGS. 7 and 8 will be omitted.

The doped patterns 101 overlap with the contact holes 501. The doped patterns 101 extend along the first direction D1, although they can alternatively be formed along the second direction D2, or formed along both directions D1 and D2 as a checkerboard pattern. The doped patterns 101 may be formed as (n++) areas doped with the first dopant at a concentration higher than that of the first doped layer 200. Thus, a potential difference between the doped patterns 101 and the second doped layer 200 may be larger than the potential difference between the first doped layer 100 and the second doped layer 200. In addition, in the present example embodiment, the contact holes 501 overlap with the doped patterns 101 to electrically connect the doped patterns 101 with the first electrode 401, thus increasing the potential difference at electrode 410, and increasing the amount of electrical power that can be generated.

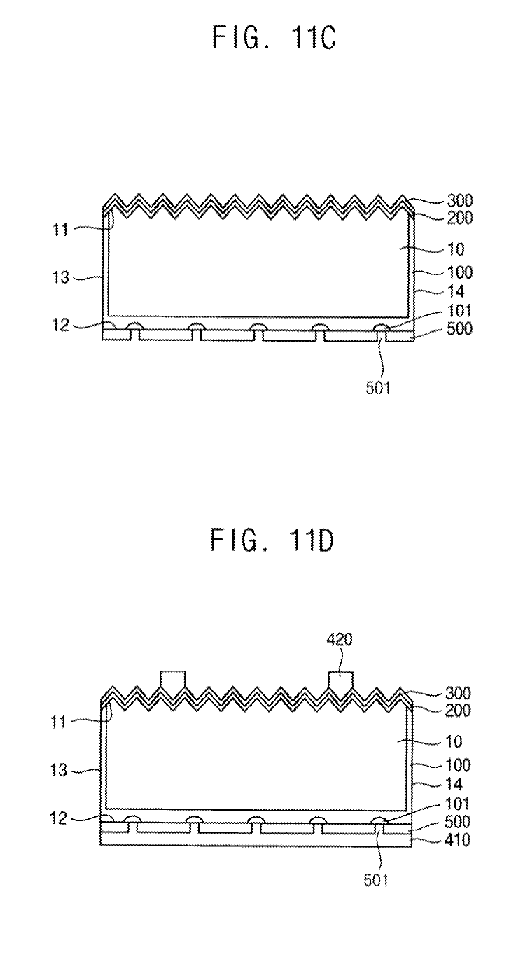

FIGS. 11A, 11B, 11C and 11D are cross-sectional views for explaining a process for manufacturing the solar cell of FIG. 9.

The method of manufacturing the solar cell according to the present example embodiments is substantially the same as the method of manufacturing of the solar cell 1 in FIG. 2, except that the anti-reflection layer 500 is formed on the first doped layer 100. Thus, substantially the same elements in FIG. 2 are referred to with the same reference numerals, and repetitive description of the same elements is omitted.

Referring to FIGS. 10, 4A to 4H, and 11A, the doped patterns 101 are formed in portions of the first doped layer 100. The doped patterns 101 may be distinguished from the first doped layer 100 by the presence of the first dopant at concentrations higher than that of the first doped layer 100. The doped patterns 101 may be formed via a doping paste method, a laser doping method, a chemical doping method, or an ion-implantation method.

Referring to FIGS. 10 and 11B, the anti-reflection layer 500 is formed on the first doped layer 100 and the doped patterns 101. The anti-reflection layer 500 may be formed via a CVD method, an evaporation method, a sputtering method, or the like.

Referring to FIGS. 10 and 11C, the contact holes 501 are formed in the anti-reflection layer 500. The contact holes 501 extend through the anti-reflection layer 500 and overlap with, so as to expose, the doped patterns 101. The anti-reflection layer 500 is partially removed by the laser (or any other suitable method) to form the contact holes 501. Alternatively, the contact holes 501 can be formed via an edge paste method, a photolithography method, etc.

Referring to FIGS. 10, 4H and 11D, the first electrode 410 is formed on the anti-reflection layer 500, and the second electrode 420 is formed on the transparent conductive layer 300. The first and second electrodes 410 and 420 are formed via a screen printing method, an ink jetprinting method, etc., and by a deforming method at a low temperature of not more than about 200° C. The first electrode 410 is electrically connected to the doped patterns 101 through the contact holes 501.

According to the present invention, a first surface into which sunlight is incident includes a concavo-convex pattern, and a second surface opposite to the first surface is flat, so that light reflectivity may be reduced or minimized. The solar cell includes a hetero junction and a relatively high terminal voltage, and thus may be used in thin-film wafers.

In addition, since most processes may be performed at a low temperature, deformations due to temperature may be reduced or minimized. Also, a protection layer is used both in removing the concavo-convex pattern and forming the doped layer via a diffusion method. Thus, the manufacturing process may be simplified.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A solar cell comprising:
a base substrate including a first surface configured to receive incident sunlight, and a second surface opposite to the first surface;
a first doped layer formed on the second surface, and including a first dopant;
a second doped layer formed on the first surface, and including a second dopant;
a first transparent conductive layer formed on the second doped layer;
a first electrode formed on the first doped layer; and
a second electrode formed on the first transparent conductive layer.

2. The solar cell of claim 1, wherein the first surface comprises a concavo-convex pattern, and the second surface is substantially flat.

3. The solar cell of claim 1, wherein the base substrate includes crystalline silicon (c-Si), and the second doped layer includes at least one of amorphous silicon (a-Si), amorphous silicon carbide (a-SiC) and amorphous silicon germanium (a-SiGe).

4. The solar cell of claim 3, wherein the first doped layer is formed via a diffusion method.

5. The solar cell of claim 1, further comprising:
a passivation layer positioned between the second surface of the base substrate and the second doped later, the passivation layer including an intrinsic semiconductor.

6. The solar cell of claim 1, wherein a thickness of the second doped layer is between about 50 Å and about 200 Å, and a thickness of the first transparent conductive layer is between about 700 Å and about 1200 Å.

7. The solar cell of claim 1, wherein each of the first and second electrodes comprises a single-layer structure including at least one of aluminum (Al), silver (Ag) and copper (Cu), or a multi-layer structure including at least one of an alloy of titanium and tungsten (TiW), tin (Sn) and nickel (Ni) in addition to at least one of aluminum (Al), silver (Ag) and copper (Cu).

8. The solar cell of claim 1, further comprising:
a second transparent conductive layer positioned between the first doped layer and the first electrode.

9. The solar cell of claim 1, further comprising:
an anti-reflection layer positioned between the first doped layer and the first electrode, the anti-reflection layer having a plurality of contact holes through which the first doped layer and the first electrode are electrically connected to each other.

10. The solar cell of claim 9, wherein the first doped layer comprises doped patterns overlapping the contact holes.

11. A method of manufacturing a solar cell, the method comprising:
forming a base substrate including a first surface for receiving sunlight, and a second surface opposite to the first surface, a protection layer being formed on the first surface;
forming a first doped layer having a first dopant, the first doped layer being formed on the second surface of the base substrate;
removing the protection layer from the first surface of the base substrate;
forming a second doped layer having a second dopant on the first surface of the base substrate;
forming a first transparent conductive layer on the second doped layer;
forming a first electrode on the first doped layer;
forming a second electrode on the first transparent conductive layer.

12. The method of claim 11, wherein the forming a base substrate further comprises:
forming a concavo-convex pattern on the first and second surfaces of the base substrate;
forming the protection layer on the first surface of the base substrate; and
removing the concavo-convex pattern from the second surface of the base substrate.

13. The method of claim 11, wherein the first doped layer is formed via a diffusion method using phosphorus oxychloride (POCl₃) or boron three bromides (BBr₃).

14. The method of claim 11, wherein the base substrate includes crystalline silicon (c-Si), and the second doped layer includes at least one of amorphous silicon (a-Si), amorphous silicon carbide (a-SiC) and amorphous silicon germanium (a-SiGe).

15. The method of claim 13, wherein the removing the protection layer further comprises:
removing a phosphor-silicate glass (PSG) layer or a boron-silicate glass (BSG) layer formed via the diffusion method; and
cleaning the base substrate, wherein the protection layer and at least one of the PSG layer and the BSG layer is removed via a wet etching process.

16. The method of claim 11, wherein the forming a second doped layer further comprises forming the second doped layer via a plasma chemical vapor deposition (PECVD) method.

17. The method of claim 11, wherein the protection layer is removed at a temperature not more than about 200° C., and the second doped layer, the first transparent conductive layer, the first electrode and the second conductive layer are formed at a temperature not more than about 200° C.

18. The method of claim 11, further comprising forming a second transparent conductive layer on the first doped layer.

19. The method of claim 11, wherein the forming a first electrode further comprises:
forming an anti-reflection layer on the first doped layer;
forming a contact hole through the anti-reflection layer; and
forming an electrode layer on the anti-reflection layer, and deforming the electrode layer.

20. The method of claim 11, further comprising:
forming a doped pattern on the first doped layer;
forming an anti-reflection layer on the first doped layer and the doped pattern; and
forming a contact hole through the anti-reflection layer, the contact hole exposing at least a portion of the doped pattern.

21. The solar cell of claim 1, wherein the first electrode is formed on substantially an entire surface of the first doped layer; and the second electrode is formed over a portion of a surface of the first transparent conductive layer.

22. The method of claim 11, wherein the forming a first electrode further comprises forming the first electrode on substantially an entire surface of the first doped layer, and the forming a second electrode further comprises forming the second electrode over a portion of a surface of the first transparent conductive layer.
